(19) United States
(12) Patent Application Publication
(10) Pub. No.: US 2025/0316589 A1
(43) Pub. Date: Oct. 9, 2025

(54) VERTICAL ANTI-FUSE STRUCTURE

(71) Applicant: INTERNATIONAL BUSINESS MACHINES CORPORATION, ARMONK, NY (US)

(72) Inventors: Ashim Dutta, Clifton Park, NY (US); Nilanka W Sirikkathuge, Guilderland, NY (US); Brandon Noland Canedy, Cohoes, NY (US); Chih-Chao Yang, Glenmont, NY (US)

(21) Appl. No.: 18/627,536

(22) Filed: Apr. 5, 2024

(51) Int. Cl. H01L 23/525

(52) U.S. Cl. CPC H01L 23/5252

(57) ABSTRACT

Embodiments of present invention provide an anti-fuse structure. The structure includes a first vertical metal pillar having a first bottom portion and a first top portion; a second vertical metal pillar having a second bottom portion and a second top portion; and a fuse dielectric between the first bottom portion of the first vertical metal pillar and the second bottom portion of the second vertical metal pillar, where a width of the first bottom portion of the first vertical metal pillar is wider than a width of the first top portion of the first vertical metal pillar or a width of the second bottom portion of the second vertical metal pillar is wider than a width of the second top portion of the second vertical metal pillar. A method of forming the same is also provided.

### BACKGROUND

The present application relates to manufacturing of semiconductor integrated circuits. More particularly, it relates to a vertical anti-fuse structure and method of forming the same.

Anti-fuse structures have been used in semiconductor industry for, for example, memory related applications, such as field programmable gate arrays (FPGA) and programmable read-only memories (ROM). An anti-fuse structure generally includes a section of material which, while initially having a relatively high resistance, may be converted into a lower resistance circuit by the application of a certain process such as a high voltage programing. After the programing, due to dielectric breakdown, the anti-fuse structure becomes conductive connecting devices and/or circuits at, for example, the top and the bottom of the anti-fuse structure together.

### SUMMARY

Embodiments of present invention provide an anti-fuse structure. The anti-fuse structure includes a first vertical metal pillar having a first bottom portion and a first top portion; a second vertical metal pillar having a second bottom portion and a second top portion; and a fuse dielectric between the first bottom portion of the first vertical metal pillar and the second bottom portion of the second vertical metal pillar, where a width of the first bottom portion of the first vertical metal pillar is wider than a width of the first top portion of the first vertical metal pillar or a width of the second bottom portion of the second vertical metal pillar is wider than a width of the second top portion of the second vertical metal pillar.

In one embodiment, a first horizontal distance between the first bottom portion of the first vertical metal pillar and the second bottom portion of the second vertical metal pillar is shorter than a second horizontal distance between the first top portion of the first vertical metal pillar and the second top portion of the second vertical metal pillar. The closer or shorter distance between the first and the second bottom portion of the first and the second vertical metal pillars ensures that dielectric breakdown happens at the fuse dielectric during programming of the anti-fuse structure.

In another embodiment, a horizontal cross-section of the first bottom portion of the first vertical metal pillar is larger than a horizontal cross-section of the first top portion of the first vertical metal pillar, and a horizontal cross-section of the second bottom portion of the second vertical metal pillar is larger than a horizontal cross-section of the second top portion of the second vertical metal pillar.

In yet another embodiment, the first and the second bottom portion of the first and the second vertical metal pillar is embedded in a first dielectric layer and the first and the second top portion of the first and the second vertical metal pillar is embedded in a second dielectric layer, the second dielectric layer being materially different from and having a different etch selectivity from the first dielectric layer.

In one embodiment, the second vertical metal pillar is in a hollow cylindrical shape, and the first vertical metal pillar is within the hollow cylindrical shape of the second vertical metal pillar. In one aspect, the first and the second vertical metal pillar form a concentric shape.

According to one embodiment, the anti-fuse structure further includes a first electrode contacting a top surface of the first vertical metal pillar and a second electrode contacting a top surface of the second vertical metal pillar.

According to another embodiment, the anti-fuse structure further includes a first electrode contacting a top surface of the first vertical metal pillar and a second electrode contacting a bottom surface of the second vertical metal pillar.

In one embodiment, the width of the first bottom portion and the width of the second bottom portion of the first and the second vertical metal pillar are respectively wider than the width of the first top portion and the width of the second top portion of the first and the second vertical metal pillar.

Embodiments of present invention further provide a method. The method includes forming a first dielectric layer on top of a supporting structure; forming a second dielectric layer on top of the first dielectric layer; creating a first opening and a second opening in the second dielectric layer and in the first dielectric layer underneath the second dielectric layer; horizontally expanding a lower portion of the first opening and a lower portion of the second opening respectively to create a first expanded opening and a second expanded opening; and filling the first expanded opening and the second expanded opening with a conductive material respectively to form a first vertical metal pillar and a second vertical metal pillar.

In one embodiment, expanding the lower portion of the first opening and the lower portion of the second opening includes selectively etching the first dielectric layer surrounding the lower portion of the first opening and the lower portion of the second opening to create, underneath the second dielectric layer, a first undercut of the first expanded opening and a second undercut of the second expanded opening.

According to one embodiment, the method further includes, before filling the first and the second expanded opening, forming a metal liner lining the first and the second expanded opening, where the metal liner is made of tantalum-nitride or titanium-nitride.

According to another embodiment, the method further includes forming a first electrode contacting a top surface of the first vertical metal pillar and a second electrode contacting a top surface of the second vertical metal pillar.

According to yet another embodiment, the method further includes applying a voltage across the first electrode and the second electrode to cause breakdown of the fuse dielectric, thereby connecting the first bottom portion of the first vertical metal pillar conductively to the second bottom portion of the second vertical metal pillar.

In one embodiment, creating the first and the second opening includes causing a second electrode embedded in the supporting structure being exposed by one of the first opening and the second opening.

In another embodiment, creating the second opening includes creating the second opening in a hollow cylindrical shape that fully surrounds the first opening.

### BRIEF DESCRIPTION OF THE DRAWINGS

The present invention will be understood and appreciated more fully from the following detailed description of embodiments of present invention, taken in conjunction with accompanying drawings of which:

FIG. 1 is a demonstrative illustration of a cross-sectional view of an anti-fuse structure at a step of manufacturing thereof according to one embodiment of present invention;

FIGS. 2A and 2B are demonstrative illustrations of a top view and a cross-sectional view of an anti-fuse structure at a step of manufacturing thereof according to one embodiment of present invention;

FIG. 3 is a demonstrative illustration of a cross-sectional view of an anti-fuse structure at a step of manufacturing thereof according to one embodiment of present invention;

FIG. 4 is a demonstrative illustration of a cross-sectional view of an anti-fuse structure at a step of manufacturing thereof according to one embodiment of present invention;

FIGS. 5A and 5B are demonstrative illustrations of a top view and a cross-sectional view of an anti-fuse structure at a step of manufacturing thereof according to one embodiment of present invention;

FIG. 6 is a demonstrative illustration of a cross-sectional view of an anti-fuse structure at a step of manufacturing thereof according to one embodiment of present invention;

FIG. 7 is a demonstrative illustration of a cross-sectional view of another anti-fuse structure at a step of manufacturing thereof according to one embodiment of present invention;

FIGS. 8A and 8B are demonstrative illustrations of a top view and a cross-sectional view of another anti-fuse structure at a step of manufacturing thereof according to one embodiment of present invention;

FIGS. 9A and 9B are demonstrative illustrations of a top view and a cross-sectional view of another anti-fuse structure at a step of manufacturing thereof according to one embodiment of present invention;

FIG. 10 is a demonstrative illustration of a cross-sectional view of another anti-fuse structure at a step of manufacturing thereof according to one embodiment of present invention;

FIGS. 11A and 11B are demonstrative illustrations of a top view and a cross-sectional view of another anti-fuse structure at a step of manufacturing thereof according to one embodiment of present invention;

FIG. 12 is a demonstrative illustration of a cross-sectional view of another anti-fuse structure at a step of manufacturing thereof according to one embodiment of present invention; and

FIG. 13 is a demonstrative illustration of a flow-chart of a method of manufacturing an anti-fuse structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

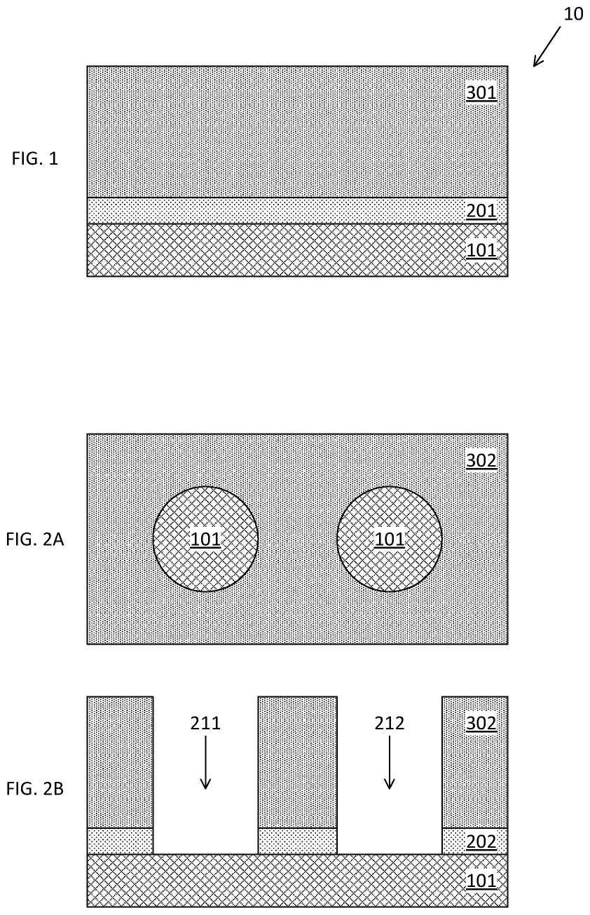

FIG. 1 is a demonstrative illustration of a cross-sectional view of an anti-fuse structure at a step of manufacturing thereof according to one embodiment of present invention. More particularly, embodiments of present invention provide forming an anti-fuse structure 10 by receiving or providing a supporting structure such as a supporting structure 101; forming a first dielectric layer 201 on top of the supporting structure 101; and forming a second dielectric layer 301 on top of the first dielectric layer 201. In one embodiment, the supporting structure 101 may be a semiconductor substrate such as a silicon (Si) substrate or a silicon-germanium (SiGe) substrate; a front-end-of-line (FEOL) structure containing one or more active devices such as transistors; a back-end-of-line (BEOL) structure containing one or more metal levels embedded in one or more dielectric layers; or a supporting layer of suitable material.

In one embodiment, the first dielectric layer 201 may be a layer of dielectric material such as, for example, silicon-nitride (SiN), silicon-oxide (SiO₂), silicon-carbide (SiC), silicon-carbonitride (SiCN), or silicon-oxycarbide (SiCOH), silicoboron-carbonitride (SiBCN), or other NBLoK dielectric material that contains atoms of silicon, carbon, hydrogen, nitrogen, and/or oxygen. The thickness and/or dielectric properties of the first dielectric layer 201, such as breakdown voltage, may be suitable or made to be suitable for forming an anti-fuse between two conductors or conductive end points. In other embodiments, instead of dielectric material, a layer of amorphous silicon may be used which may be patterned later to form an anti-fuse as well. The anti-fuse of dielectric material or amorphous silicon, during its application, may be converted into a conductive path of polysilicon through programming.

The second dielectric layer 301 may be a layer of dielectric material as well, such as SiN, SiO₂, SiC, SiCN, SiCOH, SiBCN but may have a different material composition from that of the first dielectric layer 201 such that the first dielectric layer 201 and the second dielectric layer 301 may have different etch selectivity, which enables a selective etch process as being described below in more details. In one embodiment, the thickness of the second dielectric layer 301 may be four (4) times or more of the thickness of the first dielectric layer 201. In other words, the thickness of the first dielectric layer 201 may be 25% or less of the thickness of the second dielectric layer 301.

FIGS. 2A and 2B are demonstrative illustrations of a top view and a cross-sectional view of an anti-fuse structure at a step of manufacturing thereof according to one embodiment of present invention. More particularly, following the step illustrated in FIG. 1, embodiments of present invention provide creating a first opening 211 and a second opening 212 in the second dielectric layer 301 and in the first dielectric layer 201 underneath the second dielectric layer 301. The creation of the first and the second opening 211 and 212 may be made through, for example, a lithographic patterning process followed by a directional etch process such as a reactive-ion-etch (RIE) process. The process may thus transform the second dielectric layer 301 into a second dielectric layer 302, and the first dielectric layer 201 into a first dielectric layer 202. The second dielectric layer 302 may surround a top portion of the first and the second opening 211 and 212 and the first dielectric layer 202 may surround a lower portion of the first and the second opening 211 and 212. The first and the second opening 211 and 212 may expose a top surface of the supporting structure 101 as is illustrated in FIG. 2A.

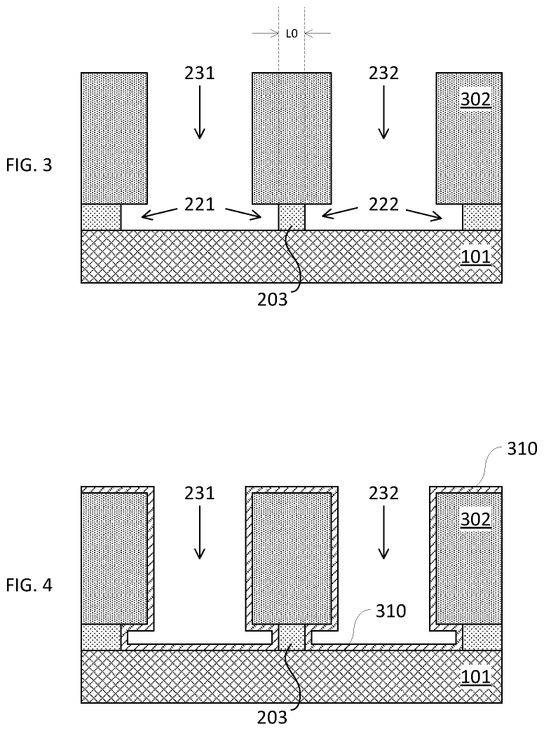

FIG. 3 is a demonstrative illustration of a cross-sectional view of an anti-fuse structure at a step of manufacturing thereof according to one embodiment of present invention. More particularly, following the step illustrated in FIGS. 2A and 2B, embodiments of present invention provide selectively etching the first dielectric layer 202, through the first and the second opening 211 and 212, thereby creating a first undercut 221 and a second undercut 222 respectively underneath the second dielectric layer 302. The first opening 211 and the first undercut 221 together form a first expanded opening 231 and the second opening 212 and the second undercut 222 together form a second expanded opening 232.

In one embodiment, the selective etching of the first dielectric layer 202 may create a fuse dielectric 203 between the first undercut 221 and the second undercut 222. The fuse dielectric 203 may have a horizontal thickness L0 ranging, for example, from about 2 nm to about 15 nm that is designed to form an anti-fuse that contacts two conductors or conductive end points to be formed in the first and the second undercut 221 and 222. When being applied a voltage at or above a breakdown voltage of the first dielectric layer 202, through programing during application of the anti-fuse structure 10, the fuse dielectric 203 may turn into or be transformed into a conductive path conductively connecting the two conductors or conductive end points.

FIG. 4 is a demonstrative illustration of a cross-sectional view of an anti-fuse structure at a step of manufacturing thereof according to one embodiment of present invention. More particularly, following the step illustrated in FIG. 3, embodiments of present invention provide forming a metal liner 310 lining the first and the second expanded opening 231 and 232. The metal liner 310 may be a conformal liner and may be made of, for example, tantalum (Ta), tantalum-nitride (TaN), titanium (Ti), titanium-nitride (TiN), ruthenium (Ru), ruthenium-nitride (RuN), ruthenium-tantalum (RuTa), ruthenium-tantalum-nitride (RuTaN), tungsten (W), tungsten-nitride (WN) or other suitable material. The metal liner 310 may be deposited through, for example, an atomic-layer-deposition (ALD) process, a chemical-vapor-deposition (CVD) process, a physical-vapor-deposition (PVD) process, or other suitable process. The metal liner 310 may have a thickness typically less than about 5 nm such as a thickness ranging from about 2 nm to about 5 nm.

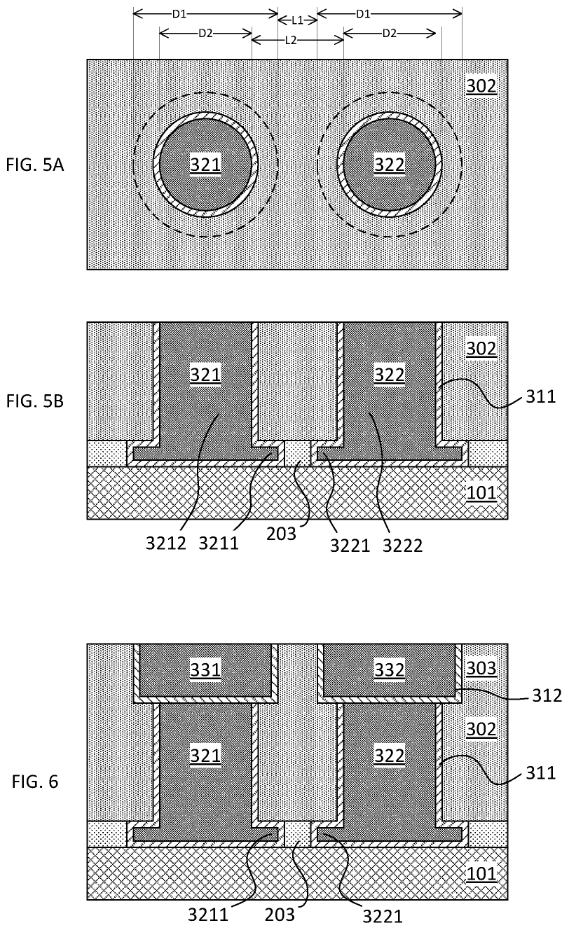

FIGS. 5A and 5B are demonstrative illustrations of a top view and a cross-sectional view of an anti-fuse structure at a step of manufacturing thereof according to one embodiment of present invention. More particularly, following the step illustrated in FIG. 4, embodiments of present invention provide filling the first and the second expanded opening 231 and 232 with a conductive material such as, for example, copper (Cu), cobalt (Co), ruthenium (Ru), aluminum (AI), tungsten (W), gold (Au), platinum (Pt), palladium (Pd), chromium (Cr), alloys thereof such as Cu-AI, or other suitable conductive material to form a first vertical metal pillar 321 and a second vertical metal pillar 322. A chemical-mechanical-polishing (CMP) process may be applied to planarize a top surface of the first and the second vertical metal pillars 321 and 322. The CMP process may also result in a metal liner 311, from the metal liner 310, lining the first and the second vertical metal pillars 321 and 322.

The first vertical metal pillar 321 may have a bottom portion 3211 and a top portion 3212. As is demonstratively illustrated in FIG. 5A, a horizontal cross-section of the bottom portion 3211 of the first vertical metal pillar 321 may be larger than a horizontal cross-section of the top portion 3212 of the first vertical metal pillar 321. Similarly, a horizontal cross-section of the bottom portion 3221 of the second vertical metal pillar 322 may be larger than a horizontal cross-section of the top portion 3222 of the second vertical metal pillar 322.

The bottom portion 3211 of the first vertical metal pillar 321 may have a width D1 and the top portion 3212 of the first vertical metal pillar 321 may have a width D2, and D1 is wider or larger than D2. Similarly, the bottom portion 3221 of the second vertical metal pillar 322 may have a width D1 and the top portion 3222 of the second vertical metal pillar 322 may have a width D2 that is smaller than D1. However, embodiments of present invention are not limited in this aspect. The width D1 of the bottom portion 3221 of the second vertical metal pillar 322 may not necessarily be the same as the width D1 of the bottom portion 3211 of the first vertical metal pillar 321, neither the width D2 of the top portion 3222 of the second vertical metal pillar 322 will necessarily be the same as the width D2 of the top portion 3212 of the first vertical metal pillar 321. In one embodiment, the top portion and the bottom portion of either the first vertical metal pillar 321 or the second vertical metal pillar 322 may have a same width but at least one of the first vertical metal pillar 321 and the second vertical metal pillar 322 has a bottom portion and a top portion and the width of the bottom portion is wider or larger than the width of the top portion.

The bottom portions 3211 and 3221 of the first and the second vertical metal pillar 321 and 322 are separated by a horizontal distance L1, and the top portions 3212 and 3222 of the first and the second vertical metal pillar 321 and 322 are separated by a horizontal distance L2. The larger horizontal cross-sections or larger width D1 of the bottom portions 3211 and 3221, than the smaller horizontal cross-sections or smaller width D2 of the top portions 3212 and 3222, makes L1 shorter or smaller than L2. The closer or shorter distance L1 between the bottom portions 3211 and 3221 of the first and the second vertical metal pillars 321 and 322 ensures that dielectric breakdown happens at the fuse dielectric 203 during programming of the anti-fuse structure 10.

FIG. 6 is a demonstrative illustration of a cross-sectional view of an anti-fuse structure at a step of manufacturing thereof according to one embodiment of present invention. More particularly, following the step illustrated in FIGS. 5A and 5B, embodiments of present invention provide forming electrodes of the anti-fuse structure 10. For example, a first electrode 331 may be formed to be in conductive contact with a top surface of the first vertical metal pillar 321, and a second electrode 332 may be formed to be in conductive contact with a top surface of the second vertical metal pillar 322. The first and the second electrode 331 and 332 may be formed to be embedded in a dielectric layer 303 and lined with a metal liner 312. However, embodiments of present invention are not limited in this aspect. The second electrode 332 may be formed in the supporting structure 101 to be in conductive contact with a bottom surface of the second vertical metal pillar 322, whose formation may be similar to a second electrode 632 as being described below in more details.

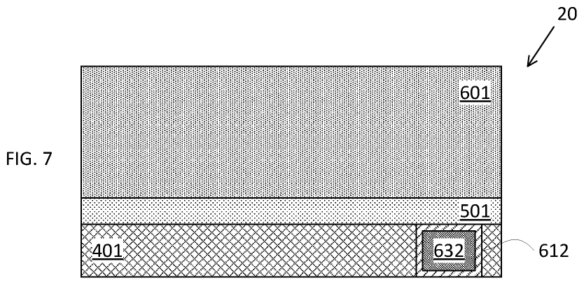

FIG. 7 is a demonstrative illustration of a cross-sectional view of another anti-fuse structure at a step of manufacturing thereof according to another embodiment of present invention. More particularly, embodiments of present invention provide forming an anti-fuse structure 20 by providing or receiving a supporting structure 401; forming a first dielectric layer 501 on top of the supporting structure 401; and forming a second dielectric layer 601 on top of the first dielectric layer 501. The supporting structure 101 may be a semiconductor substrate; a FEOL structure; a BEOL structure; or a supporting layer of other suitable materials. Additionally, according to one embodiment, the supporting structure 401 may include a second electrode 632 (a first electrode to be formed later) of the anti-fuse structure 20. A metal liner 612 may line the second electrode 632.

Similar to the anti-fuse structure 10, the first dielectric layer 501 may be a layer of dielectric material such as, for example, SiN, SiO₂, SiC, SiCN, SiCOH, SiBCN, or other NBLoK dielectric material that contains atoms of silicon, carbon, hydrogen, nitrogen, and/or oxygen. The second dielectric layer 601 may be a layer of dielectric material as well, such as those listed above, but may be different from the first dielectric layer 501 so that the first and the second dielectric layer 501 and 601 have different etch selectivity.

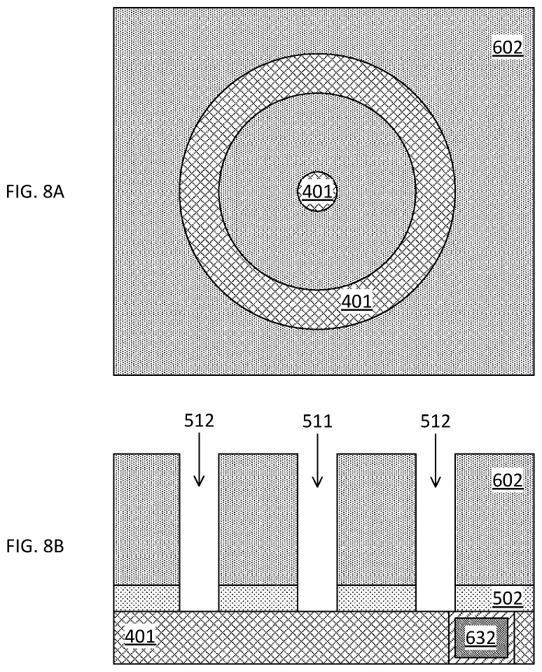

FIGS. 8A and 8B are demonstrative illustrations of a top view and a cross-sectional view of another anti-fuse structure at a step of manufacturing thereof according to one embodiment of present invention. More particularly, following the step illustrated in FIG. 7, embodiments of present invention provide creating a first opening 511 and a second opening 512 in the second dielectric layer 601 and in the first dielectric layer 501 underneath the second dielectric layer 601. The second opening 512 may be in a hollow cylindrical shape fully surrounding the first opening 511. In one embodiment, the first and the second opening may be formed concentrically. In other words, the first opening 511 may be created at a central location of hollow cylindrical shape of the second opening 512.

The process may therefore transform the first and the second dielectric layer 501 and 601 into a first and a second dielectric layer 502 and 602, which respectively includes an inner portion between the first opening 511 and the second opening 512 and an outer portion outside the second opening 512 and surrounding the second opening 512. Vertically, the second dielectric layer 602 may surround a top portion of the first and the second opening 511 and 512 and the first dielectric layer 502 may surround a lower portion of the first and the second opening 511 and 512. The first and the second opening 511 and 512 may expose a top surface of the supporting structure 401. In one embodiment, the second opening 512 may expose at least a portion of the second electrode 632 in the supporting structure 401.

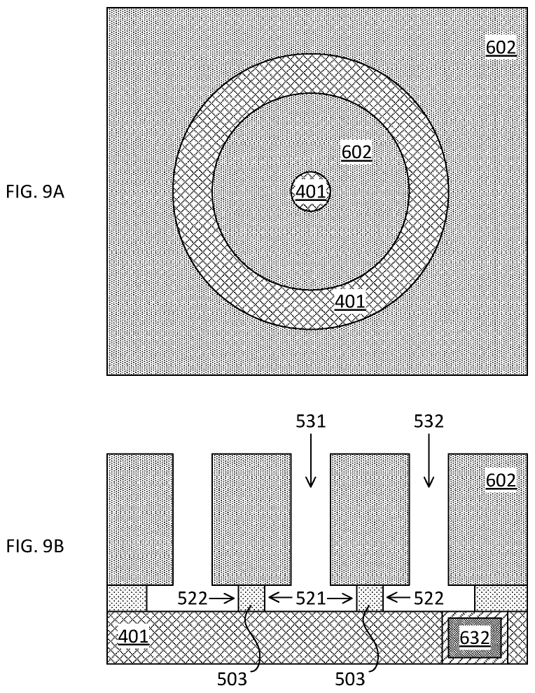

FIGS. 9A and 9B are demonstrative illustrations of a top view and a cross-sectional view of another anti-fuse structure at a step of manufacturing thereof according to one embodiment of present invention. More particularly, following the step illustrated in FIGS. 8A and 8B, embodiments of present invention provide selectively etching the first dielectric layer 502, through the first and the second opening 511 and 512, thereby creating a first undercut 521 and a second undercut 522 underneath the second dielectric layer 602. The first opening 511 and the first undercut 521 together form a first expanded opening 531 and the second opening 512 and the second undercut 522 together form a second expanded opening 532. The selective etching of the first dielectric layer 502 may create a fuse dielectric 503 between the first undercut 521 and the second undercut 522. In one embodiment, the second expanded opening 532, in particular the second undercut 522 may expose at least a portion of a top surface of the second electrode 632, such that conductive contact may be formed through the second expanded opening 532 to be in contact with the second electrode 632.

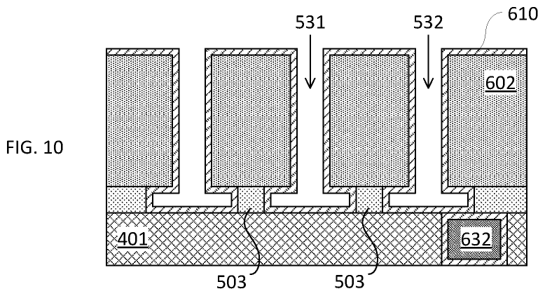

FIG. 10 is a demonstrative illustration of a cross-sectional view of another anti-fuse structure at a step of manufacturing thereof according to one embodiment of present invention. More particularly, following the step illustrated in FIGS. 9A and 9B, embodiments of present invention provide forming a metal liner 610, such as Ta, TaN, Ti, TiN, Ru, RuN, RuTa, RuTaN, W, WN, or other suitable materials, lining the first and the second expanded opening 531 and 532. The metal liner 610 may line sidewalls and particularly the first and the second undercut 521 and 522 of the first and the second expanded opening 531 and 532.

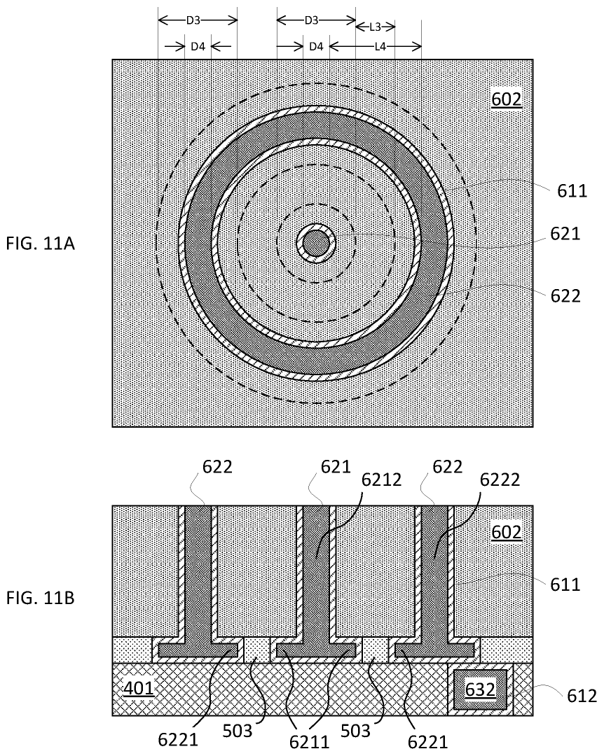

FIGS. 11A and 11B are demonstrative illustrations of a top view and a cross-sectional view of another anti-fuse structure at a step of manufacturing thereof according to one embodiment of present invention. More particularly, following the step illustrated in FIG. 10, embodiments of present invention provide filling the first and the second expanded opening 531 and 532 with a conductive material such as, for example, Cu, Co, Ru, Al, W, Au, Pt, Pd, Cr, alloys thereof such as Cu-AI, or other suitable conductive material to form a first vertical metal pillar 621 and a second vertical metal pillar 622. A CMP process may be applied to planarize a top surface of the first and the second vertical metal pillars 621 and 622. The CMP process may also result in a metal liner 611, made from the metal liner 610, lining the first and the second vertical metal pillars 621 and 622.

The first vertical metal pillar 621 may have a bottom portion 6211 and a top portion 6212. As is demonstratively illustrated in FIG. 11A, a horizontal cross-section of the bottom portion 6211 of the first vertical metal pillar 621 may be larger than a horizontal cross-section of the top portion 6212 of the first vertical metal pillar 621. The bottom portion 6211 of the first vertical metal pillar 321 thus may have a first horizontal width D3 and the top portion 6212 of the first vertical metal pillar 321 may have a first horizontal width D4 and D3 is larger than D4.

On the other hand, the second vertical metal pillar 622 may be in a hollow cylindrical shape fully surrounding the first vertical metal pillar 621. In one embodiment, the first and the second vertical metal pillar 621 and 622 may form a concentric shape. In other words, the first vertical metal pillar 621 may be positioned at a central location of the hollow cylindrical shape of the second vertical metal pillar 622.

The second vertical metal pillar 622, in a hollow cylindrical shape, may have a bottom portion 6221 with a second horizontal thickness (or width). Although embodiments of present invention are not limited in this aspect, in one embodiment the second horizontal thickness of the bottom portion 6221 of the second vertical metal pillar 622 may be the same as or equal to the first horizontal width D3 of the bottom portion 6211 of the first vertical metal pillar 621. The second vertical metal pillar 622 may also have a top portion 6222 with a second horizontal thickness (or width) that, in one embodiment, may be the same as or equal to the second horizontal width D4 of the top portion 6212 of the first vertical metal pillar 621. Moreover, the bottom portion 6221 of the second vertical metal pillar 622 may be in conductive contact, for example via metal liners 611 and 612, with the second electrode 632.

With the bottom portions being larger than the top portions, the first and the second vertical metal pillars 621 and 622 may be separated by a first distance L3 at the bottom portions thereof respectively and by a second distance L4 at the top portions thereof respectively, with the second distance L4 being larger than the first distance L3. More particularly, the bottom portions of the first and the second vertical metal pillar 621 and 622 may be separated by the fuse dielectric 503 which, when being subjected to a breakdown voltage, may turn into a conductive path or connection between the bottom portion 6211 of the first vertical metal pillar 621 and the bottom portion 6221 of the second vertical metal pillar 622. The closer or shorter distance L3 between the bottom portions 6211 and 6221 of the first and the second vertical metal pillar 621 and 622 ensures that dielectric breakdown happens at the fuse dielectric 503 during programming of the anti-fuse structure 20.

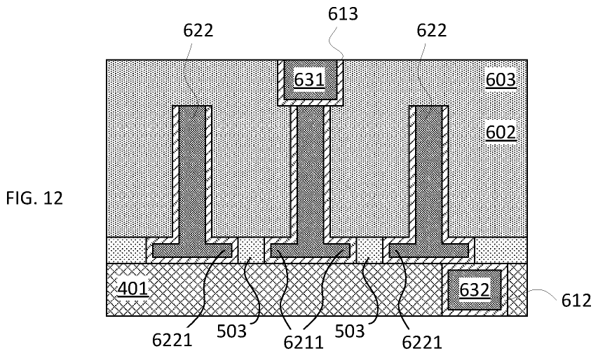

FIG. 12 is a demonstrative illustration of a cross-sectional view of another anti-fuse structure at a step of manufacturing thereof according to one embodiment of present invention. More particularly, following the step illustrated in FIGS. 11A and 11B, embodiments of present invention provide forming electrodes of the anti-fuse structure 20. For example, a dielectric layer 603 may be deposited on top of the second dielectric layer 602 covering the first and the second vertical metal pillar 621 and 622, and a first electrode 631, with a metal liner 613, may be formed inside the dielectric layer 603 to be in conductive contact with a top surface of the first vertical metal pillar 621.

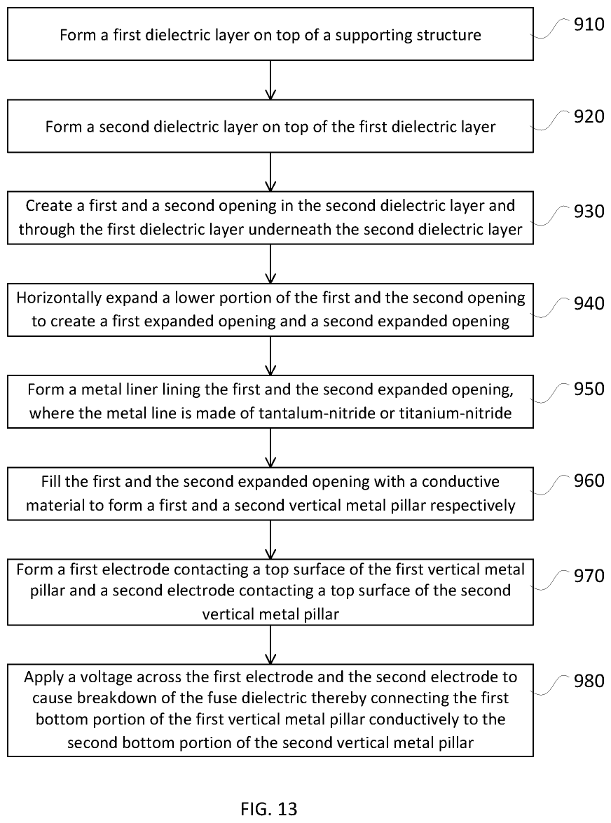

FIG. 13 is a demonstrative illustration of a flow-chart of a method of manufacturing and/or using an anti-fuse structure according to embodiments of present invention. The method includes (910) forming a first dielectric layer on top of a supporting structure; (920) forming a second dielectric layer on top of the first dielectric layer; (930) creating a first and a second opening in the second dielectric layer and through the first dielectric layer underneath the second dielectric layer; (940) horizontally expanding a lower portion of the first and the second opening to create a first expanded opening and a second expanded opening; (950) forming a metal liner lining the first and the second expanded opening, where the metal line is made of tantalum-nitride or titanium-nitride; (960) filling the first and the second expanded opening with a conductive material to form a first and a second vertical metal pillar respectively; (970) forming a first electrode contacting a top surface of the first vertical metal pillar and a second electrode contacting a top surface of the second vertical metal pillar; and (980) applying a voltage across the first electrode and the second electrode to cause breakdown of the fuse dielectric thereby connecting the first bottom portion of the first vertical metal pillar conductively to the second bottom portion of the second vertical metal pillar.

Various examples may possibly be described by one or more of the following features in the following numbered clauses:

Clause 1: An anti-fuse structure comprising a first vertical metal pillar having a first bottom portion and a first top portion; a second vertical metal pillar having a second bottom portion and a second top portion; and a fuse dielectric between the first bottom portion of the first vertical metal pillar and the second bottom portion of the second vertical metal pillar, wherein a width of the first bottom portion of the first vertical metal pillar is wider than a width of the first top portion of the first vertical metal pillar or a width of the second bottom portion of the second vertical metal pillar is wider than a width of the second top portion of the second vertical metal pillar.

Clause 2: The anti-fuse structure of clause 1, wherein a first horizontal distance between the first bottom portion of the first vertical metal pillar and the second bottom portion of the second vertical metal pillar is shorter than a second horizontal distance between the first top portion of the first vertical metal pillar and the second top portion of the second vertical metal pillar.

Clause 3: The anti-fuse structure of clause 2, wherein a horizontal cross-section of the first bottom portion of the first vertical metal pillar is larger than a horizontal cross-section of the first top portion of the first vertical metal pillar, and a horizontal cross-section of the second bottom portion of the second vertical metal pillar is larger than a horizontal cross-section of the second top portion of the second vertical metal pillar.

Clause 4: The anti-fuse structure of clause 1, wherein the first and the second bottom portion of the first and the second vertical metal pillar is embedded in a first dielectric layer and the first and the second top portion of the first and the second vertical metal pillar is embedded in a second dielectric layer, the second dielectric layer being materially different from and having a different etch selectivity from the first dielectric layer.

Clause 5: The anti-fuse structure of clause 1, wherein the second vertical metal pillar is in a hollow cylindrical shape, and the first vertical metal pillar is within the hollow cylindrical shape of the second vertical metal pillar.

Clause 6: The anti-fuse structure of clause 5, wherein the first and the second vertical metal pillar form a concentric shape.

Clause 7: The anti-fuse structure of clause 1, further comprising a first electrode contacting a top surface of the first vertical metal pillar and a second electrode contacting a top surface of the second vertical metal pillar.

Clause 8: The anti-fuse structure of clause 1, further comprising a first electrode contacting a top surface of the first vertical metal pillar and a second electrode contacting a bottom surface of the second vertical metal pillar.

Clause 9: The anti-fuse structure of clause 1, wherein the widths of the first and the second bottom portion of the first and the second vertical metal pillar are respectively wider than the widths of the first and the second top portion of the first and the second vertical metal pillar.

Clause 10: A method comprising forming a first dielectric layer on top of a supporting structure; forming a second dielectric layer on top of the first dielectric layer; creating a first opening and a second opening in the second dielectric layer and in the first dielectric layer underneath the second dielectric layer; horizontally expanding a lower portion of the first opening and a lower portion of the second opening respectively to create a first expanded opening and a second expanded opening; and filling the first expanded opening and the second expanded opening with a conductive material respectively to form a first vertical metal pillar and a second vertical metal pillar.

Clause 11: The method of clause 10, wherein expanding the lower portion of the first opening and the lower portion of the second opening comprises selectively etching the first dielectric layer surrounding the lower portion of the first opening and the lower portion of the second opening to create, underneath the second dielectric layer, a first undercut of the first expanded opening and a second undercut of the second expanded opening.

Clause 12: The method of clause 10, further comprising, before filling the first and the second expanded opening, forming a metal liner lining the first and the second expanded opening, wherein the metal liner is made of tantalum-nitride or titanium-nitride.

Clause 13: The method of clause 10, further comprising forming a first electrode contacting a top surface of the first vertical metal pillar and a second electrode contacting a top surface of the second vertical metal pillar.

Clause 14: The method of clause 13, further comprising applying a voltage across the first electrode and the second electrode to cause breakdown of the fuse dielectric, thereby connecting the first bottom portion of the first vertical metal pillar conductively to the second bottom portion of the second vertical metal pillar.

Clause 15: The method of clause 10, wherein creating the first and the second opening comprises causing a second electrode embedded in the supporting structure being exposed by one of the first opening and the second opening.

Clause 16: The method of clause 10, wherein creating the second opening comprises creating the second opening in a hollow cylindrical shape that fully surrounds the first opening.

Clause 17: An anti-fuse structure comprising a first vertical metal pillar having a first bottom portion and a first top portion; a second vertical metal pillar having a second bottom portion and a second top portion; a fuse dielectric between the first bottom portion of the first vertical metal pillar and the second bottom portion of the second vertical metal pillar; a first electrode contacting a top surface of the first vertical metal pillar; and a second electrode contact one of a top surface and a bottom surface of the second vertical metal pillar, wherein a width of the first bottom portion of the first vertical metal pillar is wider than a width of the first top portion of the first vertical metal pillar and a width of the second bottom portion of the second vertical metal pillar is wider than a width of the second top portion of the second vertical metal pillar.

Clause 18: The anti-fuse structure of clause 17, wherein a first horizontal distance between the first bottom portion of the first vertical metal pillar and the second bottom portion of the second vertical metal pillar is shorter than a second horizontal distance between the first top portion of the first vertical metal pillar and the second top portion of the second vertical metal pillar.

Clause 19: The anti-fuse structure of clause 17, wherein the first and the second bottom portion of the first and the second vertical metal pillar is embedded in a first dielectric layer and the first and the second top portion of the first and the second vertical metal pillar is embedded in a second dielectric layer that is materially different and has a different etch selectivity from the first dielectric layer.

Clause 20: The anti-fuse structure of clause 17, wherein the second vertical metal pillar is in a hollow cylindrical shape, and the first vertical metal pillar and the second vertical metal pillar form a concentric shape.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. An anti-fuse structure comprising:
a first vertical metal pillar having a first bottom portion and a first top portion;
a second vertical metal pillar having a second bottom portion and a second top portion; and
a fuse dielectric between the first bottom portion of the first vertical metal pillar and the second bottom portion of the second vertical metal pillar,
wherein a width of the first bottom portion of the first vertical metal pillar is wider than a width of the first top portion of the first vertical metal pillar or a width of the second bottom portion of the second vertical metal pillar is wider than a width of the second top portion of the second vertical metal pillar.

2. The anti-fuse structure of claim 1, wherein a first horizontal distance between the first bottom portion of the first vertical metal pillar and the second bottom portion of the second vertical metal pillar is shorter than a second horizontal distance between the first top portion of the first vertical metal pillar and the second top portion of the second vertical metal pillar.

3. The anti-fuse structure of claim 2, wherein a horizontal cross-section of the first bottom portion of the first vertical metal pillar is larger than a horizontal cross-section of the first top portion of the first vertical metal pillar, and a horizontal cross-section of the second bottom portion of the second vertical metal pillar is larger than a horizontal cross-section of the second top portion of the second vertical metal pillar.

4. The anti-fuse structure of claim 1, wherein the first and the second bottom portion of the first and the second vertical metal pillar is embedded in a first dielectric layer and the first and the second top portion of the first and the second vertical metal pillar is embedded in a second dielectric layer, the second dielectric layer being materially different and having a different etch selectivity from the first dielectric layer.

5. The anti-fuse structure of claim 1, wherein the second vertical metal pillar is in a hollow cylindrical shape, and the first vertical metal pillar is within the hollow cylindrical shape of the second vertical metal pillar.

6. The anti-fuse structure of claim 5, wherein the first and the second vertical metal pillar form a concentric shape.

7. The anti-fuse structure of claim 1, further comprising a first electrode contacting a top surface of the first vertical metal pillar and a second electrode contacting a top surface of the second vertical metal pillar.

8. The anti-fuse structure of claim 1, further comprising a first electrode contacting a top surface of the first vertical metal pillar and a second electrode contacting a bottom surface of the second vertical metal pillar.

9. The anti-fuse structure of claim 1, wherein the widths of the first and the second bottom portion of the first and the second vertical metal pillar are respectively wider than the widths of the first and the second top portion of the first and the second vertical metal pillar.

10. A method comprising:
forming a first dielectric layer on top of a supporting structure;
forming a second dielectric layer on top of the first dielectric layer;
creating a first opening and a second opening in the second dielectric layer and in the first dielectric layer underneath the second dielectric layer;
horizontally expanding a lower portion of the first opening and a lower portion of the second opening respectively to create a first expanded opening and a second expanded opening; and
filling the first expanded opening and the second expanded opening with a conductive material respectively to form a first vertical metal pillar and a second vertical metal pillar.

11. The method of claim 10, wherein expanding the lower portion of the first opening and the lower portion of the second opening comprises selectively etching the first dielectric layer surrounding the lower portion of the first opening and the lower portion of the second opening to create, underneath the second dielectric layer, a first undercut of the first expanded opening and a second undercut of the second expanded opening.

12. The method of claim 10, further comprising, before filling the first and the second expanded opening, forming a metal liner lining the first and the second expanded opening, wherein the metal liner is made of tantalum-nitride or titanium-nitride.

13. The method of claim 10, further comprising forming a first electrode contacting a top surface of the first vertical metal pillar and a second electrode contacting a top surface of the second vertical metal pillar.

14. The method of claim 13, further comprising applying a voltage across the first electrode and the second electrode to cause breakdown of the fuse dielectric, thereby connecting the first bottom portion of the first vertical metal pillar conductively to the second bottom portion of the second vertical metal pillar.

15. The method of claim 10, wherein creating the first and the second opening comprises causing a second electrode embedded in the supporting structure being exposed by one of the first opening and the second opening.

16. The method of claim 10, wherein creating the second opening comprises creating the second opening in a hollow cylindrical shape that fully surrounds the first opening.

17. An anti-fuse structure comprising:
a first vertical metal pillar having a first bottom portion and a first top portion;
a second vertical metal pillar having a second bottom portion and a second top portion;
a fuse dielectric between the first bottom portion of the first vertical metal pillar and the second bottom portion of the second vertical metal pillar;
a first electrode contacting a top surface of the first vertical metal pillar; and
a second electrode contact one of a top surface and a bottom surface of the second vertical metal pillar,
wherein a width of the first bottom portion of the first vertical metal pillar is wider than a width of the first top portion of the first vertical metal pillar and a width of the second bottom portion of the second vertical metal pillar is wider than a width of the second top portion of the second vertical metal pillar.

18. The anti-fuse structure of claim 17, wherein a first horizontal distance between the first bottom portion of the first vertical metal pillar and the second bottom portion of the second vertical metal pillar is shorter than a second horizontal distance between the first top portion of the first vertical metal pillar and the second top portion of the second vertical metal pillar.

19. The anti-fuse structure of claim 17, wherein the first and the second bottom portion of the first and the second vertical metal pillar is embedded in a first dielectric layer and the first and the second top portion of the first and the second vertical metal pillar is embedded in a second dielectric layer that is materially different and has a different etch selectivity from the first dielectric layer.

20. The anti-fuse structure of claim 17, wherein the second vertical metal pillar is in a hollow cylindrical shape, and the first vertical metal pillar and the second vertical metal pillar form a concentric shape.
